(19) United States
(12) Patent Application Publication
(10) Pub. No.: US 2024/0297087 A1
(43) Pub. Date: Sep. 5, 2024

(54) PACKAGE MODULE WITH A MODULE STIFFENER AND METHODS OF FORMING THE SAME

(71) Applicant: Taiwan Semiconductor Manufacturing Company Limited, Hsinchu (TW)

(72) Inventors: Sheng-Kai CHANG, Taipei City (TW); Chih-Kang Han, Hsinchu City (TW); Leo Li, Hsinchu (TW); Lieh-Chuan Chen, Hsinchu City (TW); Chien-Li Kuo, Hsinchu City (TW)

(21) Appl. No.: 18/115,840

(22) Filed: Mar. 1, 2023

(51) Int. Cl. H01L 23/16; H01L 21/48; H01L 21/56; H01L 23/31; H01L 23/498; H01L 23/538; H01L 25/065

(52) U.S. Cl. CPC H01L 23/16; H01L 21/4853; H01L 21/561; H01L 21/565; H01L 21/568; H01L 23/3128; H01L 23/3135; H01L 23/49816; H01L 23/49833; H01L 23/49838; H01L 23/5386; H01L 25/0655; H01L 21/563; H01L 24/16; H01L 24/32; H01L 24/73; H01L 24/96; H01L 24/97; H01L 2224/16227; H01L 2224/32225; H01L 2224/73204; H01L 2224/96; H01L 2224/97; H01L 2924/1011

(57) ABSTRACT

A package module includes an interposer, a plurality of semiconductor dies on the interposer, a module stiffener on the interposer adjacent to the plurality of semiconductor dies, and a molding material layer on the interposer around the plurality of semiconductor dies and the module stiffener.

### BACKGROUND

A package structure may be formed without a package lid. However, the lidless package structures may suffer from warpage (bending). Warpage may be a result of a differential coefficient of thermal expansion (CTE) between different bonded layers, e.g., silicon and organic substrate, in the package structure. A stiffener ring (e.g., circumferential copper stiffener ring) may be affixed to the package substrate to mitigate warpage, but for large packages a stiffener ring may be inadequate in reducing warpage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package module according to one or more embodiments.

FIG. 1B is a plan view (e.g., top-down view) of the package module according to one or more embodiments.

FIG. 1C is a detailed vertical cross-sectional view of the module stiffener according to one or more embodiments.

FIG. 2A is a vertical cross-sectional view of an intermediate structure including an interposer (e.g., organic interposer) formed on a carrier substrate (e.g., carrier wafer) according to an embodiment of the present invention.

FIG. 2B is a vertical cross-sectional view of an intermediate structure including the first semiconductor die and the second semiconductor die according to one or more embodiments.

FIG. 2C is a vertical cross-sectional view of an intermediate structure including the package module underfill layer according to one or more embodiments

FIG. 2D illustrates a vertical cross-sectional view of an intermediate structure in which the adhesive may be applied to the interposer according to one or more embodiments.

FIG. 2E illustrates a vertical cross-sectional view of an intermediate structure in which the module stiffener may be attached to (e.g., mounted on) the interposer according to one or more embodiments.

FIG. 2F illustrates a vertical cross-sectional view of an intermediate structure including the molding material layer according to one or more embodiments.

FIG. 2G illustrates a vertical cross-sectional view of an intermediate structure including the plurality of C4 bumps, according to one or more embodiments.

FIG. 2H is a plan view (top-down view) of an intermediate structure including the package module before a singulation process, according to one or more embodiments.

FIG. 2I is a vertical cross-sectional view of the intermediate structure including the package module after the singulation process, according to one or more embodiments.

FIG. 3 is a flow chart illustrating a method of forming a package structure according to one or more embodiments.

FIG. 4A illustrates a first alternative design in which the module stiffener may include a plurality of disconnected stiffener segments, according to one or more embodiments.

FIG. 4B illustrates a second alternative design in which the module stiffener may include a plurality of disconnected stiffener segments, according to one or more embodiments.

FIG. 4C illustrates a third alternative design in which the module stiffener may include a plurality of disconnected stiffener segments, according to one or more embodiments.

FIG. 4D illustrates a fourth alternative design in which the module stiffener may include a center line stiffener segment, according to one or more embodiments.

FIG. 4E illustrates a fifth alternative design in which the module stiffener may include a plurality of disconnected stiffener segments, according to one or more embodiments.

FIG. 5 is a vertical cross-sectional view of the package module having a first alternative design, according to one or more embodiments.

FIG. 6 is a vertical cross-sectional view of a package structure including the package module, according to one or more embodiments.

FIG. 7 is a vertical cross-sectional view of a package structure having a first alternative design, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Presently, package structures (e.g., 2.5D/3D package die sizes) are increasing in size in order to provide greater performance. However, large package structures (e.g., having a size 5 cm by 5 cm or larger), may increase the likelihood of die warpage and make die warpage more difficult to control. Consequently, there may be a small window for flip-chip bonding processes. Die warpage may also be induced by the application of multi-organic redistribution layers (RDL layers). A complex floorplan design may also result in an unpredictable die warpage and result in a high localized stress.

One or more embodiments of the present disclosure may provide a novel package module (e.g., packaging die) having a design (e.g., die design) with a module stiffener (e.g., an embedded module stiffener) to control overall die warpage. The design may not only enlarge a flip-chip window but may also improve rigidity of a corner of the package module (e.g., a corner of a packaging die). The module stiffener may mitigate control warpage of the package module at low and high temperatures. In particular, the module stiffener may improve corner stress (e.g., reliability-related corner stress) by selecting a proper material (e.g., a material having a proper coefficient of thermal expansion (CTE)) for the module stiffener.

The module stiffener may be included in the package module during a wafer forming process (e.g., a current 300 mm wafer forming process). The module stiffener may, therefore, be used in a mass production of package modules. The module stiffener may reduce or eliminate the need for a package stiffener formed around the module stiffener on a package substrate. The module stiffener may thereby reduce a size of the package substrate and, therefore, decrease (e.g., shorten) a footprint of a package structure (e.g., reduce an area of the package structure) including the package module.

A material of the module stiffener may include, for example, any kind of metal, alloy, polymer, semiconductor or a combination (e.g., composite) of any of these materials. The module stiffener may include a foreign material attached on a substrate (e.g., a base wafer, interposer wafer, etc.) and may be adhered/affixed to the substrate (e.g., stuck onto the substrate) such as by adhesive.

A shape (e.g., structure) of the module stiffener may be any shape. A thickness (e.g., in the z-direction) of the module stiffener may be in a range from about 0.1 mm to about 5.0 mm. In at least one embodiment, a minimum thickness of the module stiffener may be about 0.5 mm. In at least one embodiment, the thickness of the module stiffener may be less than a thickness of the semiconductor dies in the package module. The module stiffener may or may not be exposed at the upper surface of a molding material layer in which the module stiffener is embedded. The module stiffener may have no active or passive device function.

In at least one embodiment, a process flow for making the package module may include, for example, mounting semiconductor dies on an interposer wafer (e.g., RDL and die attachment), attaching the module stiffener to the interposer wafer (e.g., module stiffener attachment), depositing molding material (e.g., epoxy molding compound (EMC)) around the semiconductor dies and the module stiffener, and grinding the molding material to have an upper surface substantially coplanar with an upper surface of the semiconductor dies.

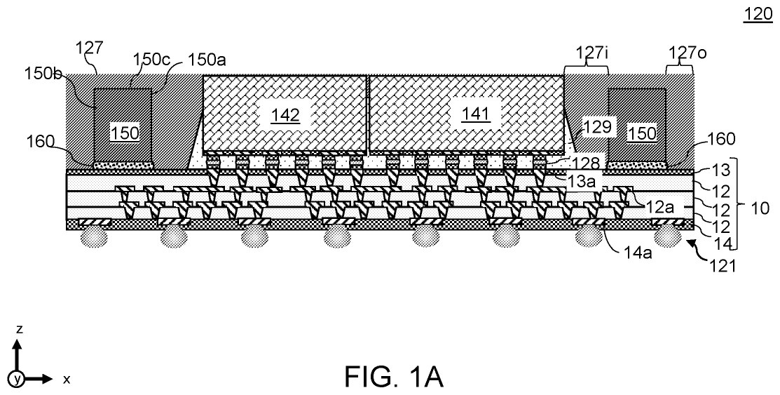

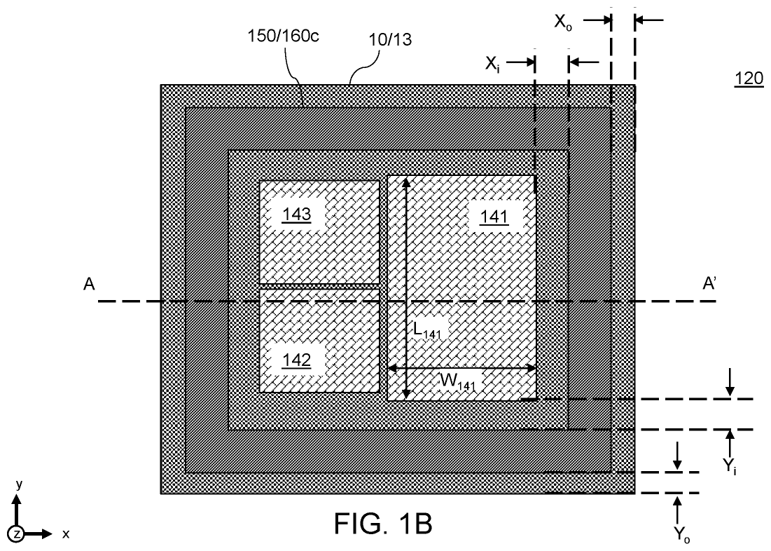

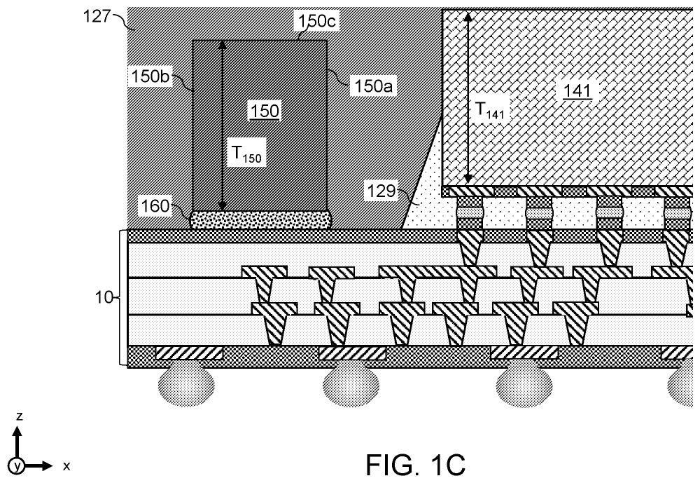

FIG. 1A is a vertical cross-sectional view of a package module 120 according to one or more embodiments. FIG. 1B is a plan view (e.g., top-down view) of the package module 120 according to one or more embodiments. The vertical cross-sectional view in FIG. 1A is along the line A-A′ in FIG. 1B. The package module 120 may include a first semiconductor die 141, second semiconductor die 142 and third semiconductor die 143 (not shown in FIG. 1A), on an interposer 10.

Although the package module 120 is illustrated in FIGS. 1A and 1B as including three (3) semiconductor dies having a particular arrangement, the number of semiconductor dies and the arrangement of the semiconductor dies is not limited to the number and arrangement in FIGS. 1A and 1B. In particular, the first semiconductor die 141, second semiconductor die 142 and third semiconductor die 143 may constitute a semiconductor die set, and the package module 120 may include a plurality of the semiconductor die sets.

The interposer 10 which may include organic material (e.g., dielectric polymer), inorganic material (e.g., silicon), glass substrate, etc. In at least one embodiment, the interposer 10 may include a plurality of polymer layers 12 and a plurality of redistribution layers 12a stacked alternately. The number of the polymer layers 12 and/or the number of redistribution layers 12a in the interposer 10 is not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals. Other suitable conductive materials are within the contemplated scope of disclosure.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layers 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12, and may extend in the x-direction (first horizontal direction) and y-direction (second horizontal direction) on an upper surface of the polymer layers 12.

An upper passivation layer 13 may be formed on the chip-side surface of the interposer 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more interposer upper bonding pads 13a may be formed in the upper passivation layer 13 on the chip-side surface of interposer 10. The upper passivation layer 13 may at least partially cover the interposer upper bonding pads 13a. That is, the interposer upper bonding pads 13a may be at least partially exposed on the chip-side surface of the interposer 10. The interposer upper bonding pads 13a may be connected to the redistribution layers 12a. The interposer upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer 10. The lower passivation layer 14 may include silicon oxide, silicon nitride, low-k dielectric materials such as carbon-doped oxides, extremely low-k dielectric materials such as porous carbon doped silicon dioxide, a combination thereof or other suitable material.

One or more interposer lower bonding pads 14a may be located in the lower passivation layer 14 on the board-side surface of interposer 10. The lower passivation layer 14 may at least partially cover the interposer lower bonding pads 14a. That is, the interposer lower bonding pads 14a may be at least partially exposed on the board-side surface of the interposer 10. The interposer lower bonding pads 14a may be connected to the redistribution layers 12a. The interposer lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package module 120 may also include one or more semiconductor dies (e.g., semiconductor chips) mounted on the chip-side surface of the interposer 10. In particular, the first semiconductor die 141, second semiconductor die 142 and third semiconductor die 143 (not shown) may be mounted (e.g., flip-chip mounted) on the chip-side surface of the interposer 10. The first semiconductor die 141, second semiconductor die 142 and third semiconductor die 143 may be mounted on the interposer 10, for example, by microbumps 128. The microbumps 128 may each include a copper post and a solder bump on the copper post. The microbumps 128 may be bonded to the interposer upper bonding pads 13a. The microbumps 128 may be electrically connected through the interposer upper bonding pads 13a to the redistribution layers 12a in the interposer 10.

A package module underfill layer 129 may be formed under and around the first semiconductor die 141, second semiconductor die 142 and third semiconductor die 143 and the microbumps 128 so as to affix the first semiconductor die 141, second semiconductor die 142 and third semiconductor die 143 to the interposer 10. The package module underfill layer 129 may be formed of an epoxy-based polymeric material.

Each of the first semiconductor die 141, second semiconductor die 142 and third semiconductor die 143 may include, for example, a semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the first semiconductor die 141, second semiconductor die 142 and third semiconductor die 143 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

In at least one embodiment, the first semiconductor die 141 may include a primary die, and the second semiconductor die 141 and third semiconductor die 143 may each include an ancillary die. In at least one embodiment, the first semiconductor die 141 may include an SOC die, and the second semiconductor die 142 and the third semiconductor die 143 may each include a memory die (e.g., memory/SOC die, HBM die, etc.).

The package module 120 may also include a module stiffener 150 (e.g., an embedded module stiffener) on the chip-side surface of the interposer 10 (e.g., on the upper passivation layer 13). The module stiffener 150 may be located adjacent to one or more of the first semiconductor die 141, second semiconductor die 142 and third semiconductor die 143. The module stiffener 150 may be adhered (e.g., affixed) to the interposer 10 by an adhesive 160 (e.g., buffer layer). The adhesive 160 may include, for example, a silicone adhesive or an epoxy adhesive. Other suitable adhesives may be used.

In an alternative design, the package module 120 may include a plurality of semiconductor die sets, with each semiconductor die set including the first semiconductor die 141, second semiconductor die 142 and third semiconductor die 143. In such an alternative design, the module stiffener 150 may be located adjacent to each of the semiconductor die sets.

The module stiffener 150 may have no active or passive device function. The module stiffener 150 may provide rigidity to the interposer 10, and thereby help to control overall die warpage in the package module 120. In particular, the module stiffener 150 may help to control warpage of the package module 120 at low and high temperatures, and may also improve rigidity of a corner of the package module 120. In particular, by selecting a proper material (e.g., a material having a proper coefficient of thermal expansion (CTE)) for the module stiffener 150, the module stiffener 150 may improve a corner stress (e.g., reliability-related corner stress) in the package module 120.

The module stiffener 150 may include, for example, any kind of metal, alloy, polymer, semiconductor or a combination (e.g., composite) of any of these materials. In at least one embodiment, the module stiffener 150 may include one or more layers of copper or copper alloy. In at least one embodiment, the module stiffener 150 may include a metal such as copper with a nickel coating, or an aluminum alloy. A shape (e.g., structure) of the module stiffener 150 may include any shape.

The module stiffener 150 may have an inner sidewall 150a facing the semiconductor dies (e.g., first semiconductor die 141, second semiconductor die 142 and third semiconductor die 143), and an outer sidewall 150b facing away from the semiconductor dies. The inner sidewall 150a and outer sidewall 150b may extend in the z-direction substantially perpendicular to the chip-side surface of the interposer 10. The inner sidewall 150a and outer sidewall 150b may have a substantially uniform (e.g., flat) surface. The module stiffener 150 may also have an upper surface 150c extending from the inner sidewall 150a to the outer sidewall 150b.

The package module 120 may also include a molding material layer 127 formed on and around the module stiffener 150. The module stiffener 150 may or may not be exposed at the upper surface of the molding material layer 127.

In at least one embodiment, the molding material layer 127 may be formed on (e.g., cover) the inner sidewall 150a, outer sidewall 150b and upper surface 150c of the module stiffener 150. That is, the module stiffener 150 may be “embedded” within the molding material layer 127. The molding material layer 127 may also be formed on and around the first semiconductor die 141, the second semiconductor die 142, the third semiconductor die 143, the package module underfill layer 129 and the interposer 10.

The molding material layer 127 may also be formed between each of the first semiconductor die 141, the second semiconductor die 142, and third semiconductor die 143. In at least one embodiment, the molding material layer 127 may be bonded, for example, to one or more of the chip-side surface of the interposer 10 (e.g., the upper surface of the upper passivation layer 13), a sidewall of the first semiconductor die 141, a sidewall of the second semiconductor die 142, a sidewall of the third semiconductor die 143, the inner sidewall 150a of the module stiffener 150, the outer sidewall 150b of the module stiffener 150, the upper surface 150c of the module stiffener 150, the package module underfill layer 129, and the adhesive 160.

As illustrated in FIG. 1A, the molding material layer 127 may include an inner molding material layer portion 127i inside the module stiffener 150 (e.g., between the module stiffener 150 and the semiconductor dies (e.g., first semiconductor die 141, second semiconductor die 142 and third semiconductor die 143). The molding material layer 127 may also include an outer molding material layer portion 127o outside the module stiffener 150 (e.g., between the module stiffener 150 and the outer sidewall of the molding material layer 127). A width (in the x-direction) of the inner molding material layer portion 127i may be greater than a width of the outer molding material layer portion 127o. In at least one embodiment, the width (in the x-direction) of the inner molding material layer portion 127i may be greater than 1.25 times the width of the outer molding material layer portion 127o.

An upper surface of the molding material layer 127 may be substantially uniform (e.g., flat). The upper surface may also be substantially coplanar with an upper surface of the first semiconductor die 141, an upper surface of the second semiconductor die 142 and an upper surface of the third semiconductor die 143. A sidewall of the molding material layer 127 may be substantially aligned with a sidewall of the interposer 10.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a material that is substantially similar to the package module underfill layer 129. In at least one embodiment, the molding material layer 127 may include a polymeric material and in particular, an epoxy-based polymeric material. Other suitable molding materials may be used.

In at least one embodiment, the molding material layer 127 may have a CTE that is substantially similar to a CTE of the interposer 10 and/or a CTE of the module stiffener 150. In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

As further illustrated in FIG. 1A, a plurality of C4 bumps 121 may connected to the interposer lower bonding pads 14a on the board-side surface of the interposer 10, respectively. In at least one embodiment, the C4 bumps 121 may include a solder bump formed on the lower bonding pads 14a, for example, by an electroplating process. In at least one embodiment, the C4 bumps 121 may include a solder bump (e.g., SnAg solder bump) on a contact pad (e.g., copper/nickel contact pad). The package module 120 may be connected to a substrate such as a package substrate through the C4 bumps 121.

Referring again to FIG. 1B, it should be noted that the molding material layer 127 covering the upper surface 150c of the module stiffener 150 has been omitted from the figure for ease of understanding and viewing the dimensions of the width of the inner molding material layer portion 127i as well as the outer molding material layer portion 127o. As illustrated in FIG. 1B, the second semiconductor die 142 and third semiconductor die 143 may be located on a side (in the x-direction) of the first semiconductor die 141. A size of each of the second semiconductor die 142 and third semiconductor die 143 may be less than a size of the first semiconductor die 141. In particular, an area (in the x-y plane) of each of the second semiconductor die 142 and third semiconductor die 143 may be less than an area of the third semiconductor die 141.

As further illustrated in FIG. 1B, the module stiffener 150 may have a ring-shape. In particular, the module stiffener 150 may include a module stiffener ring formed around an entire periphery of the first semiconductor die 141, second semiconductor die 142 and third semiconductor die 143. A width of the module stiffener 150 may be substantially uniform around the entire periphery of the first semiconductor die 141, second semiconductor die 142 and third semiconductor die 143. It should be noted that in the alternative design where the package module 120 includes a plurality of semiconductor die sets (with each semiconductor die set including the first semiconductor die 141, second semiconductor die 142 and third semiconductor die 143) the module stiffener 150 may be located around all of the semiconductor die sets.

An outer distance Xₒ in the x-direction between the module stiffener 150 and the outer sidewall of the interposer 10 may be greater than 0.8 mm. An outer distance Yₒ in the y-direction between the module stiffener 150 and the outer sidewall of the interposer 10 may also be greater than 0.8 mm. Thus, a distance between the module stiffener 150 and the outer sidewall of the interposer 10 around the entire periphery of the module stiffener 150 may be greater than 0.8 mm. Thus, in at least one embodiment, the outer molding material layer portion 127o (see FIG. 1A) outside the module stiffener ring, may have a width in the x-direction and the y-direction greater than about 0.8 mm.

The inner distance between the module stiffener 150 and the semiconductor dies (e.g., first semiconductor die 141, second semiconductor die 142 and third semiconductor die 143) may be subject to at least two constraints. Under a first constraint, a minimum inner distance Xᵢ in the x-direction between the module stiffener 150 and the semiconductor dies (e.g., first semiconductor die 141, second semiconductor die 142 and third semiconductor die 143) may be 2 mm. In addition, a minimum inner distance Yᵢ in the y-direction between the module stiffener 150 and the semiconductor dies (e.g., first semiconductor die 141, second semiconductor die 142 and third semiconductor die 143) may also be 2 mm. That is, under the first constraint, a minimum distance between the module stiffener 150 and the semiconductor dies (e.g., first semiconductor die 141, second semiconductor die 142 and third semiconductor die 143) around the entire periphery of the semiconductor dies may be 2 mm.

Under a second constraint, the minimum inner distance Xᵢ and the minimum inner distance Yᵢ may depend in a size of the largest semiconductor die (by area) of the semiconductor dies (e.g., first semiconductor die 141, second semiconductor die 142 and third semiconductor die 143). For example, in FIG. 1B, the semiconductor die having the largest area is the first semiconductor die 141 which has a width W₁₄₁ in the x-direction and a length L₁₄₁ in the y-direction. Under the second constraint, the minimum inner distance Xᵢ may be given by W₁₄₁×0.7, and the minimum inner distance Yᵢ may be given by L₁₄₁×0.7.

Thus, pursuant to the first and second constraints, the minimum inner distance Xᵢ may be considered to be the greater of 2 mm or (W₁₄₁×0.7), and the minimum inner distance Yᵢ may be considered to be 2 mm or (L₁₄₁×0.7). Thus, in at least one embodiment, the inner molding material layer portion 127i (see FIG. 1A) outside the module stiffener ring, may have a width in the x-direction and the y-direction greater than about 2 mm.

FIG. 1C is a detailed vertical cross-sectional view of the module stiffener 150 according to one or more embodiments. As illustrated in FIG. 1C, the module stiffener 150 may have a thickness T150 (in the z-direction) that is substantially uniform over the width of the module stiffener 150 (e.g., between the inner sidewall 150a and the outer sidewall 150b).

The thickness T150 of the module stiffener 150 may be in a range from 100 μm to 5000 μm. In at least one embodiment, the thickness T₁₅₀ of the module stiffener 150 may be based on a greatest thickness of the semiconductor dies (of the first semiconductor die 141, second semiconductor die 142 and third semiconductor die 143). Generally, the thicknesses of the first semiconductor die 141, second semiconductor die 142 and third semiconductor die 143 may be substantially the same. In that case, the thickness T₁₅₀ of the module stiffener 150 may be based on the thickness T₁₄₁ of the first semiconductor die 141 illustrated in FIG. 1C. In particular, a ratio of the thickness T₁₅₀ of the module stiffener 150 to the thickness T₁₄₁ of the first semiconductor die 141 may be in a range from 0.1:1 to 1:1.

In at least one embodiment, a height (e.g., distance from chip-side surface of interposer 10) of the upper surface 150c of the module stiffener 150 may be based on a greatest height of the semiconductor dies (of the first semiconductor die 141, second semiconductor die 142 and third semiconductor die 143). Generally, the heights of an upper surface of the first semiconductor die 141, an upper surface of the second semiconductor die 142 and an upper surface of the third semiconductor die 143 may be substantially the same. In that case, the height of the upper surface 150c of the module stiffener 150 may be less than the height of the upper surface of the first semiconductor die 141 as illustrated in FIG. 1C, and the module stiffener 150 may be unexposed at the upper surface of the molding material layer 127. Alternatively, the height of the upper surface 150c of the module stiffener 150 may be equal to the height of the upper surface of the semiconductor die 143, and the module stiffener 150 may be exposed at the upper surface of the molding material layer 127.

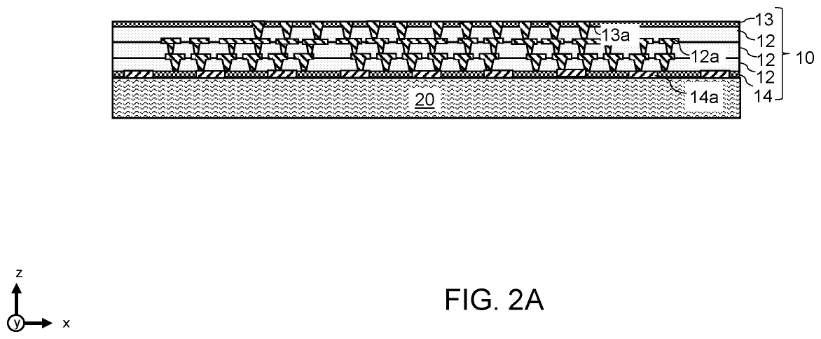

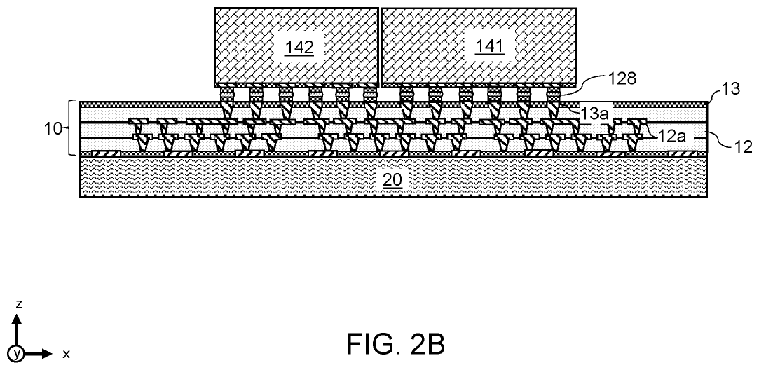

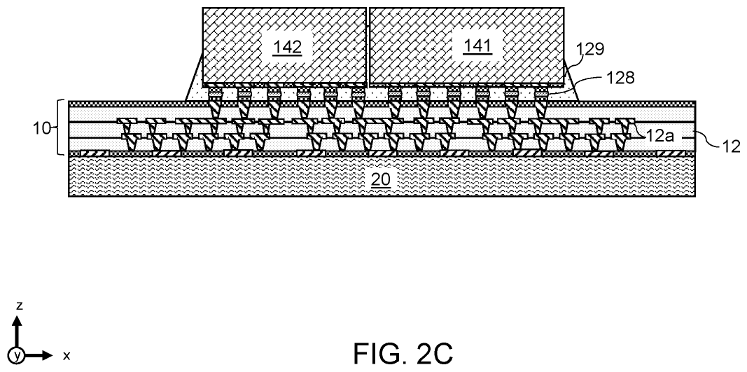

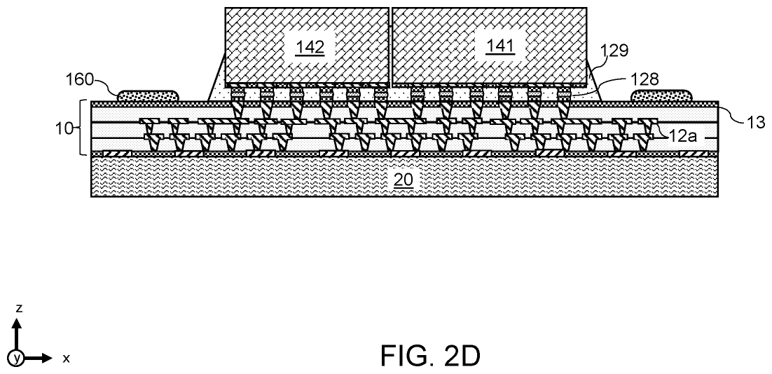

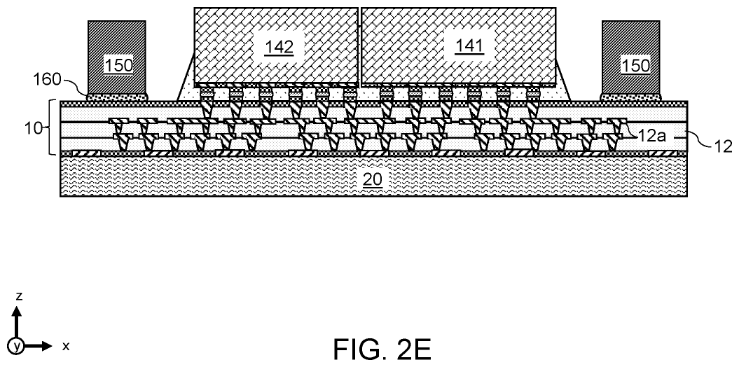

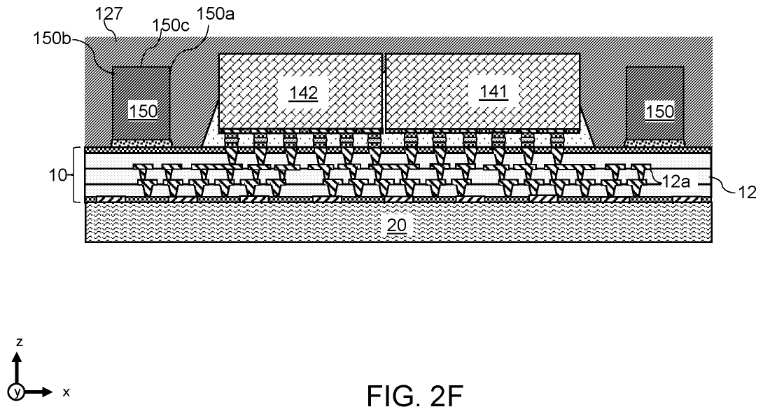

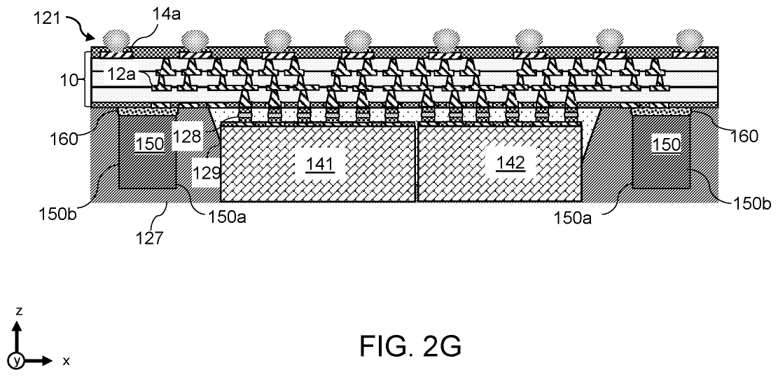

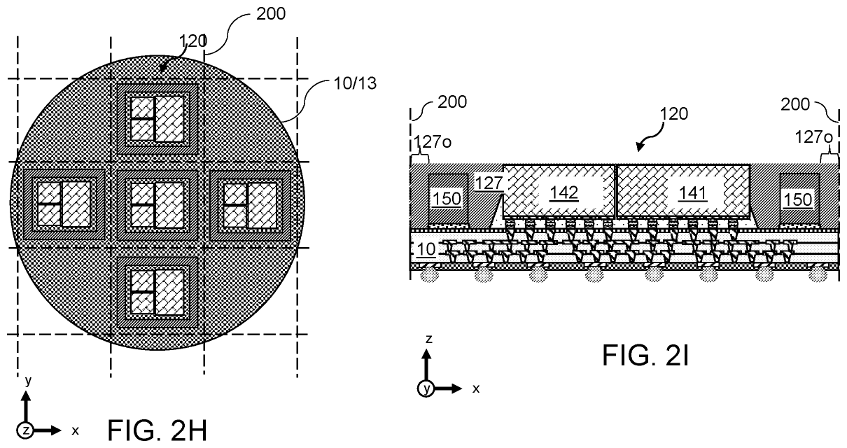

FIGS. 2A-2F illustrate various intermediate structures in a method of forming the package module 120 according to one or more embodiments. FIG. 2A is a vertical cross-sectional view of an intermediate structure including an interposer 10 (e.g., organic interposer) formed on a carrier substrate 20 (e.g., carrier wafer) according to an embodiment of the present invention. The carrier substrate 20 may be a circular wafer or a rectangular wafer. The lateral dimensions (such as the diameter of a circular wafer or a side of a rectangular wafer) of the carrier substrate 20 may be in a range from 100 mm to 500 mm, such as from 200 mm to 400 mm, although lesser and greater lateral dimensions may also be used. The carrier substrate 20 may include a semiconductor substrate, an insulating substrate, or a conductive substrate. The carrier substrate 20 may be transparent or opaque. The thickness of the carrier substrate 20 may be sufficient to provide mechanical support to an array of interposers to be formed thereupon. For example, the thickness of the carrier substrate 20 may be in a range from 60 microns to 1 mm, although lesser and greater thicknesses may also be used.

An adhesive layer (not shown) may be applied to the top surface of the carrier substrate 20. In one embodiment, the carrier substrate 20 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

The interposer lower bonding pads 14a may be formed on the adhesive layer. The interposer lower bonding pads 14a may include any metallic material that may be bonded to a solder material. The interposer lower bonding pads 14a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.). The metal layer may then be patterned by a photolithographic process so as to form the interposer lower bonding pads 14a. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the interposer lower bonding pads 14a may include an underbump metallurgy (UBM) layer stack deposited over the adhesive layer. The order of material layers within the UBM layer stack may be selected such that solder material portions may be subsequently bonded to portions of the bottom surface of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the interposer lower bonding pads 14a. In at least one embodiment, the interposer lower bonding pads 14a may be arranged as a two-dimensional array, which may be a two-dimensional periodic array such as a rectangular periodic array. In at least one embodiment, the interposer lower bonding pads 14a may be formed as controlled collapse chip connection (C4) bump structures.

The lower passivation layer 14 may then be formed on the board-side surface of the interposer 10 and over the interposer lower bonding pads 14a. The lower passivation layer 14 may be formed by depositing (e.g., by CVD, PVD or other suitable deposition technique) one or more layers of passivation material including silicon oxide, silicon nitride, low-k dielectric materials such as carbon-doped oxides, extremely low-k dielectric materials such as porous carbon doped silicon dioxide, a combination thereof or other suitable material. The passivation material may then be planarized (e.g., by wet etching, drying etching, etc.) so as to form the lower passivation layer 14.

A plurality of dielectric layers 12 and plurality of redistribution layers 12a may then be alternately formed on the lower passivation layer 14 and interposer lower bonding pads 14a. It should be noted that although FIG. 2A illustrates three dielectric layers 12 and three redistribution layers 12a, more or fewer dielectric layers 12 and redistribution layers 12a are contemplated by the present disclosure.

Each dielectric layer 12 may each be formed, for example, by depositing (e.g., by CVD, PVD or other suitable deposition technique) a layer of dielectric polymer material such as polyimide (PI), benzocyclobutene (BCB), or polybenzobisoxazole (PBO). Other suitable materials are within the contemplated scope of disclosure. The thickness of the layer of dielectric polymer material may be in a range from 4 microns to 60 microns, although lesser and greater thicknesses may also be used. The dielectric layer 12 may then be patterned by a photolithographic process to form via holes in the dielectric layer 12. The photolithographic process may include forming a patterned photoresist mask (not shown) on the layer of dielectric material, and etching (e.g., wet etching, dry etching, etc.) the exposed upper surface of the dielectric material through openings in the photoresist mask. The photoresist mask may be subsequently removed by ashing, dissolving the photoresist mask or by consuming the photoresist mask during the etch process.

A redistribution layer 12a (e.g., metal traces and metal vias) may then be formed on the dielectric layer 12. The redistribution layer 12a may be formed, for example, by depositing (e.g., by CVD, PVD or other suitable deposition technique) one or more layers of metal material such as copper, aluminum, nickel, titanium, a combination thereof or other suitable metals, on the dielectric layer 12 and in the vias holes formed by patterning the dielectric layer 12. The redistribution layer 12a may then be patterned by a photolithographic process. The photolithographic process may include forming a patterned photoresist mask (not shown) on the layer of metal material, and etching (e.g., wet etching, dry etching, etc.) the exposed upper surface of the metal material through openings in the photoresist mask. The photoresist mask may be subsequently removed by ashing, dissolving the photoresist mask or by consuming the photoresist mask during the etch process.

As further illustrated in FIG. 2A, the interposer upper bonding pads 13a may then be formed on the uppermost dielectric layer 12. The interposer upper bonding pads 13a may be formed by a process similar to that described above with respect to the interposer lower bonding pads 14a. The upper passivation layer 13 may then be formed on the uppermost dielectric layer 12 and the interposer upper bonding pads 13a. The upper passivation layer 13 may be formed by a process similar to that described above with respect to the lower passivation layer 14.

FIG. 2B is a vertical cross-sectional view of an intermediate structure including the first semiconductor die 141 and the second semiconductor die 142 according to one or more embodiments. The first semiconductor die 141, second semiconductor die 142 and third semiconductor die 143 (not shown) may be placed on the interposer module 10, for example, by using a electromechanical pick-and-place (PNP) machine.

Each of the first semiconductor die 141, second semiconductor die 142 and third semiconductor die 143 may be bonded to a respective subset of the interposer upper bonding pads 13a. The first semiconductor die 141, second semiconductor die 142 and third semiconductor die 143 may be electrically coupled to each other by one or more redistribution layers 12a in the interposer 10.

Each of the first semiconductor die 141, second semiconductor die 142 and third semiconductor die 143 may be bonded to the interposer 10 by one or more microbumps 128. In at least one embodiment, the microbumps 128 may include a two-dimensional array of microbumps 128, and each of the first semiconductor die 141, second semiconductor die 142 and third semiconductor die 143 may be attached to the interposer upper bonding pads 13a by C2 bonding, (e.g., solder bonding). A C2 bonding process that reflows the solder portions of the microbumps 128 may be performed after bump structures of the semiconductor dies (e.g., first semiconductor die 141, second semiconductor die 142 and third semiconductor die 143) are disposed over the interposer upper bonding pads 13a.

FIG. 2C is a vertical cross-sectional view of an intermediate structure including the package module underfill layer 129 according to one or more embodiments. The package module underfill layer 129 may be applied by depositing and/or injecting an epoxy-based polymeric material onto the interposer 10. The epoxy-based polymeric material may be applied on the interposer 10 so as to be formed under and around the microbumps 128. The package module underfill layer 129 may then be cured, for example, in a box oven for about 90 minutes at about 150° C. to provide the package module underfill layer 129 with a sufficient stiffness and mechanical strength.

FIG. 2D illustrates a vertical cross-sectional view of an intermediate structure in which the adhesive 160 may be applied to the interposer 10 according to one or more embodiments. The adhesive 160 may include, for example, a silicone adhesive or an epoxy adhesive. The adhesive 160 may be dispensed onto the interposer 10 so as to be located at a position corresponding to a placement of the module stiffener 150. In particular, the adhesive 160 may be formed as a continuous bead around an entire periphery of the semiconductor dies (e.g., first semiconductor die 141, second semiconductor die 142, third semiconductor die 143). The adhesive 160 may be dispensed, for example, by a suitable dispensing tool. The adhesive 160 may be dispensed onto the chip-side surface of the interposer 10 (e.g., upper surface of the upper passivation layer 13) in a quantity sufficient to securely bond the module stiffener 150 to the interposer 10.

FIG. 2E illustrates a vertical cross-sectional view of an intermediate structure in which the module stiffener 150 may be attached to (e.g., mounted on) the interposer 10 according to one or more embodiments. In at least one embodiment, the module stiffener 150 may be attached to the interposer 10 by the adhesive 160.

In at least one embodiment, the module stiffener 150 may be attached to the interposer 10 by placing the intermediate structure of FIG. 2D on a flat, solid surface such as a table-top. The module stiffener 150 may then be lowered down onto the interposer 10 around the semiconductor dies (e.g., first semiconductor die 141, second semiconductor die 142, third semiconductor die 143). The module stiffener 150 may then be aligned with the adhesive 160 formed on the interposer 10. The module stiffener 150 may then be pressed downward by applying a pressing force down onto the module stiffener 150 so that the module stiffener 150 may be affixed to the interposer 10 through the adhesive 160. Alternatively, the module stiffener 150 may be placed on the flat, solid surface, and the interposer 10 inverted and lowered onto the module stiffener 150. That is, the semiconductor dies (e.g., first semiconductor die 141, second semiconductor die 142, third semiconductor die 143) may be inserted into the module stiffener 150. The interposer 10 and semiconductor dies (e.g., first semiconductor die 141, second semiconductor die 142, third semiconductor die 143) may then be pressed by applying a pressing force down onto the carrier substrate 20 so that the module stiffener 150 is affixed to the package substrate 110 through the adhesive 160.

The module stiffener 150 may be clamped to the package substrate 110 for a period to allow the adhesive 160 to cure and form a secure bond between the package substrate 110 and the module stiffener 150. The clamping of the module stiffener 150 to the package substrate 110 may be performed, for example, by using a heat clamp module. The heat clamp module may apply a uniform force across the upper surface of the module stiffener 150.

FIG. 2F illustrates a vertical cross-sectional view of an intermediate structure including the molding material layer 127 according to one or more embodiments. The molding material layer 127 may be formed by dispensing a liquid molding material (e.g., epoxy molding material) onto the intermediate structure of FIG. 2E by a suitable dispensing tool. The molding material layer 127 may be dispensed onto the intermediate structure so as to have a height greater than a height of the upper surface 150c of the module stiffener 150, upper surface of the first semiconductor die 141, upper surface of the second semiconductor die 142 and upper surface of the third semiconductor die 143.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the interposer 10, a size of the interposer 10, a size of the first semiconductor die 141, a size of the second semiconductor die 142, a size of the third semiconductor die 143, a size of the module stiffener 150, etc.

In at least one embodiment, the molding material of the molding material layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around module stiffener 150, the first semiconductor die 141, second semiconductor die 142 and third semiconductor die 143. The low viscosity may also help to avoid the formation of voids in the molding material layer 127. In at least one embodiment, the molding material layer 127 may be substantially free of voids.

After the molding material layer 127 has been adequately cured, the molding material layer 127 may be planarized so as to make the upper surface of the molding material layer 127 to be substantially coplanar with the upper surface of the first semiconductor die 141, second semiconductor die 142 and third semiconductor die 143. The molding material layer 127 may be planarized, for example, by grinding, chemical mechanical polishing (CMP) or other suitable planarization technique.

FIG. 2G illustrates a vertical cross-sectional view of an intermediate structure including the plurality of C4 bumps 121, according to one or more embodiments. After the molding material layer 127 has been cured and planarized (e.g., by grinding, CMP, etc.), the carrier substrate 20 may be detached from the interposer 10. The carrier substrate 20 may be detached from the interposer 10, for example, by deactivating the adhesive layer (not shown) adhering the carrier substrate to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The plurality of C4 bumps 121 may then be formed on the intermediate structure. The C4 bumps 121 may include, for example, solder balls formed on the interposer lower bonding pads 14a, for example, by an electroplating process. The plurality of C4 bumps 121 may contact the interposer lower bonding pads 14a through openings in the lower passivation layer 14. In at least one embodiment, one or more underbump metallization (UBM) layers (not shown) may be formed on the interposer lower bonding pads 14a. The plurality of C4 bumps 121 may then be formed so as to contact the interposer lower bonding pads 14a through the UBM layers.

FIG. 2H is a plan view (top-down view) of an intermediate structure including the package module 120 before a singulation process, according to one or more embodiments. The molding material layer 127 is omitted from FIG. 2H for ease of understanding. As illustrated in FIG. 2H, a plurality of the package modules 120 may be formed concurrently on the interposer 10 (e.g., interposer wafer) in a wafer-level process. After the forming of the C4 bumps 121, a singulation process may be performed in order to singulate the package modules 120. The singulation process may be performed, for example, by using a dicing saw to saw the interposer 10 (and the molding material 127 formed thereon) along dicing lines 200 that are located outside the module stiffener 150. In particular, the dicing lines 200 may be located around the entire periphery of the module stiffener 150 and sufficiently distant (e.g., greater than 0.8 mm) from the module stiffener 150.

FIG. 2I is a vertical cross-sectional view of the intermediate structure including the package module 120 after the singulation process, according to one or more embodiments. As illustrated in FIG. 2I, in the singulation process, the dicing line 200 may be located at a position around module stiffener 150 so that the outer molding material layer portion 127o has a width of greater than 0.8 mm.

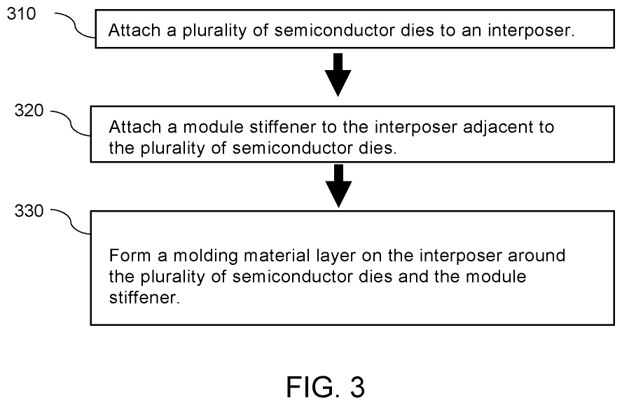

FIG. 3 is a flow chart illustrating a method of forming a package structure according to one or more embodiments. Step 310 includes attaching a plurality of semiconductor dies to an interposer. Step 320 includes attaching a module stiffener to the interposer adjacent to the plurality of semiconductor dies. Step 330 includes forming a molding material layer on the interposer around the plurality of semiconductor dies and the module stiffener.

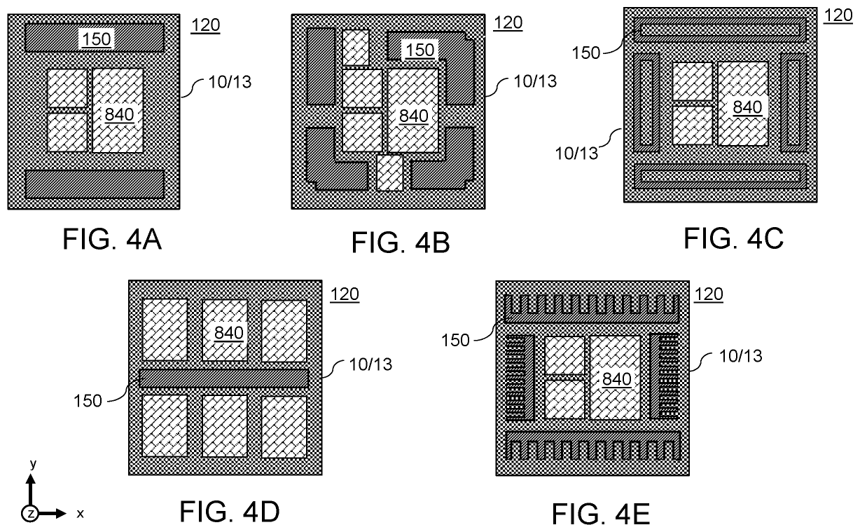

FIGS. 4A-4E are plan views of alternative designs of the module stiffener 150 according to one or more embodiments. In each of the alternative designs in FIGS. 4A-4E, the module stiffener 150 may maintain a minimum distance from the semiconductor dies 840 of 2 mm, and maintain a minimum distance from the outer edge of the interposer 10 of greater than 0.8 mm. Further, in each of the alternative designs in FIGS. 4A-4E, the molding material layer 127 (not shown) may be formed around each of the stiffener segments in the alternative designs, as described above with respect to the original design of the module stiffener 150 in FIGS. 1A-1C.

In particular, FIG. 4A illustrates a first alternative design in which the module stiffener 150 may include a plurality of disconnected stiffener segments, according to one or more embodiments. In the first alternative design, two stiffener segments of the module stiffener 150 may be arranged on opposite sides of semiconductor dies 840. In particular, the two stiffener segments may be parallel and on opposing sides of the package module 120.

FIG. 4B illustrates a second alternative design in which the module stiffener 150 may include a plurality of disconnected stiffener segments, according to one or more embodiments. In the second alternative design, the module stiffener 150 may include a plurality of disconnected stiffener segments including one or more angled corner stiffener segments and one or more linear stiffener segments.

FIG. 4C illustrates a third alternative design in which the module stiffener 150 may include a plurality of disconnected stiffener segments, according to one or more embodiments. In the third alternative design, the module stiffener 150 may include a plurality of disconnected stiffener segments including a plurality of rectangular shape stiffener segments. The plurality of rectangular shape stiffener segments may have different sizes and may be formed around the outer perimeter of the semiconductor dies 840. The plurality of rectangular shape stiffener segments may include a pair of long rectangular shape stiffener segments arranged longitudinally in the x-direction, and a pair of short rectangular shape stiffener segments arranged longitudinally in the y-direction.

FIG. 4D illustrates a fourth alternative design in which the module stiffener 150 may include a center line stiffener segment, according to one or more embodiments. In the fourth alternative design, the module stiffener 150 may include one or more center line stiffener segments located on or near a center of the package module 120. The center line stiffener segment may extend longitudinally in the x-direction and separate a first portion of the semiconductor dies 840 from a second portion of semiconductor dies 840. The first portion of the semiconductor dies 840 and the second portion of semiconductor dies 840 may include the same number of semiconductor dies 840 and may be arranged symmetrically with respect to the center line stiffener segment.

FIG. 4E illustrates a fifth alternative design in which the module stiffener 150 may include a plurality of disconnected stiffener segments, according to one or more embodiments. In the fifth alternative design, the module stiffener 150 may include a plurality of comb-shaped stiffener segments. The comb-shaped stiffener segments may be arranged so as to face outwardly away from the semiconductor devices 840. The plurality of comb-shaped stiffener segments may have different sizes and may be formed around the outer perimeter of the semiconductor dies 840. The plurality of comb-shaped stiffener segments may include a pair of long comb-shaped stiffener segments arranged longitudinally in the x-direction, and a pair of short comb-shaped stiffener segments arranged longitudinally in the y-direction.

It should be noted that other designs of the module stiffener 150 may be contemplated by the present disclosure. In particular, the module stiffener 150 may include a plurality of disconnected stiffener segments having different widths in the x-direction and lengths in the y-direction. In particular, the module stiffener 150 may include a first disconnected stiffener segment having a first width and a second disconnected stiffener segment having a second width different than the first width. The module stiffener 150 may include a first disconnected stiffener segment having a first thickness (in the z-direction) and a second disconnected stiffener segment having a second thickness different than the first thickness.

In addition, the module stiffener 150 may include a first disconnected stiffener segment including a first material (e.g., first metal) and a second disconnected stiffener segment including a second material (e.g., second metal) different than the first material. The module stiffener 150 may include a first disconnected stiffener segment including a first property (e.g., first CTE) and a second disconnected stiffener segment having a second property (e.g., second CTE) different than the first property. In at least one embodiment, the module stiffener 150 may include disconnected stiffener segments having different shapes, materials and/or properties that are arranged in a customized arrangement based a predicted location of warpage in the package module 120.

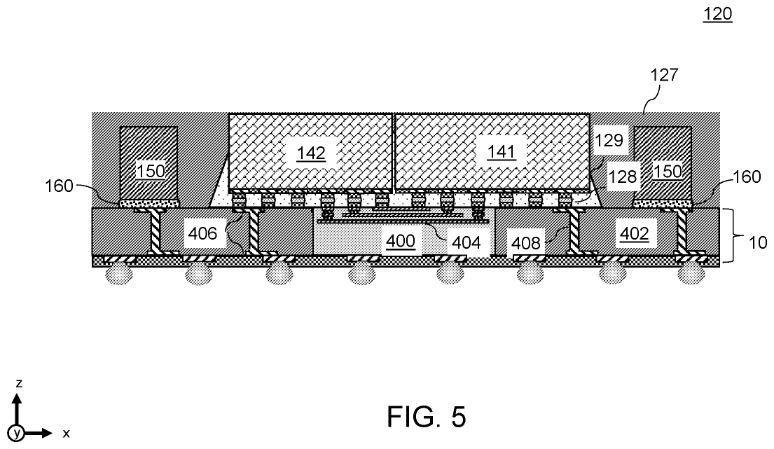

FIG. 5 is a vertical cross-sectional view of the package module 120 having a first alternative design, according to one or more embodiments. In the first alternative design, the package module 120 may include a molding-based interposer 10 including a local silicon interconnect (LSI) die 400 embedded in an interposer molding material layer 402. The interposer molding material layer 402 may include, for example, a material substantially similar to the material of the molding material layer 127. The LSI die 400 may include a plurality of interconnect lines 404 for interconnecting the first semiconductor die 141, second semiconductor die 142 and third semiconductor die 143 (not shown). In at least one embodiment, the plurality of interconnect lines 404 may provide a high routing density die-to-die interconnect through multiple layers of sub-micron metal (e.g., copper) lines. The interconnect lines 404 may provide the LSI die 400 with a plurality of different connection architectures (e.g., SoC to SoC, SoC to chiplet, SoC to HBM, etc.). The interconnect lines 404 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The molding-based interposer 10 may also integrate additional elements, such as a stand-alone integrated passive device (IPD) (not shown) underneath one or more of the semiconductor dies (e.g., first semiconductor die 141; an SoC die) to support signal communication. The molding-based interposer 10 may also include RDL layers 406 on a chip-side surface (e.g., upper surface) of the molding-based interposer 10 and on a board-side surface (e.g., lower surface) of the molding-based interposer 10. The RDL layers 406 may include a wide pitch and may be connected to through interposer vias (TIVs) 408 in the interposer molding material layer 402 for efficient signal and power delivery. The RDL layers 406 and the TIVs 408 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. With such a configuration, the molding-based interposer 10 may provide low loss of high frequency signal in high-speed transmission.

In the first alternative design, the module stiffener 150 may be formed on the molding-based interposer 10 in the same manner as in the original design of FIGS. 1A-1C. As with the original design, the module stiffener 150 may provide rigidity to the molding-based interposer 10, and thereby help to control overall die warpage in the package module 120.

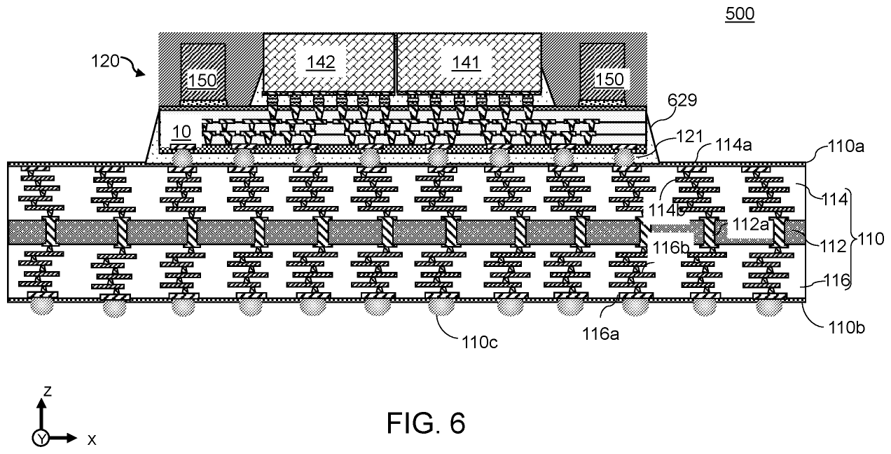

FIG. 6 is a vertical cross-sectional view of a package structure 500 including the package module 120, according to one or more embodiments. As illustrated in FIG. 6, the package structure 500 may include a package substrate 110, and the package module 120 on the package substrate 110.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 114a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate lower dielectric layer 116. The solder balls 110c may allow the semiconductor package 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b.

The package module 120 may be connected to the package substrate 110 by the C4 bumps 121 on the board-side surface of the interposer 10. In particular, the C4 bumps 121 may be bonded (e.g., using solder reflow, compression bonding, thermocompression bonding, etc.) to the package substrate upper bonding pads 114a of the package substrate 110.

A package underfill layer 629 may be formed under and around the interposer 10 and the C4 bumps 121 so as to affix the package module 120 to the package substrate 110. A material of the package underfill layer 629 may be substantially the same or different from a material of the package module underfill layer 129. In at least one embodiment, the package underfill layer 629 may be formed of an epoxy-based polymeric material.

With the configuration of the package structure 500, the module stiffener 150 of the package module 120 may help to control warpage of the package module 120 at low and high temperatures. By controlling warpage of the package module 120, the module stiffener 150 may thereby control warpage of the package substrate 110. The module stiffener 150 may thereby improve reliability of the package structure 500.

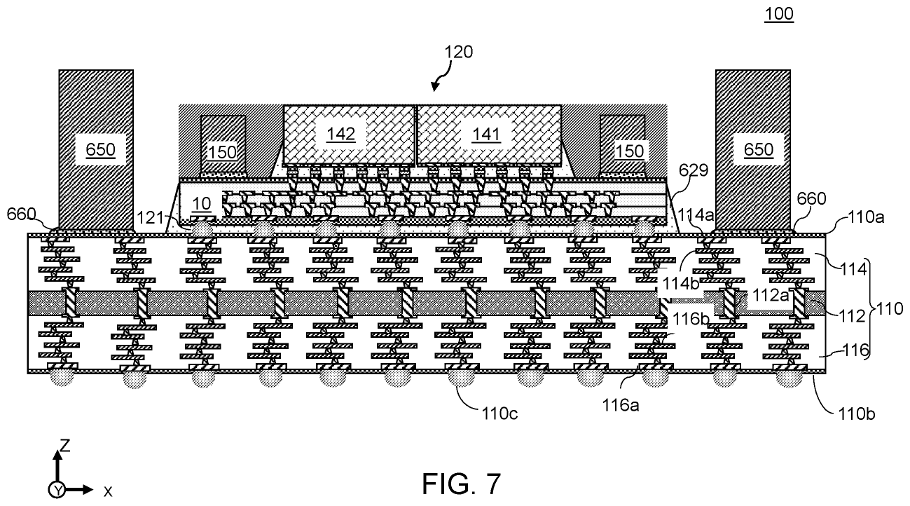

FIG. 7 is a vertical cross-sectional view of a package structure 500 having a first alternative design, according to one or more embodiments. As illustrated in FIG. 7, the first alternative design of the package structure 500 may include a package stiffener 650 on the package substrate 110. The first alternative design of the package structure 500 may be substantially the same as the original design of the package structure 500 in FIG. 6, except that the first alternative design includes the package stiffener 650.

The package stiffener 650 may mounted on the package substrate 110 around the package module 120. In at least one embodiment, the package stiffener 650 may be formed around an entire periphery of the package module 120 in the x-y plane. An upper height (in the z-direction) of the package stiffener 650 may be greater than an upper height of the package module 120. The package stiffener 650 may be securely affixed to the package substrate 110 by an adhesive 660 (e.g., a silicone adhesive or an epoxy adhesive). A material and properties (e.g., CTE) of the package stiffener 650 may be substantially the same or different from the material and properties of the module stiffener 150. In at least one embodiment, the package stiffener 650 may be formed of a metal such as copper with a nickel coating, or an aluminum alloy.

The package stiffener 650 may provide further rigidity to the package substrate 110, in addition to the rigidity provided by the module stiffener 150. The module stiffener 150 in the package module 120 may combine with the package stiffener 650 in the package structure 500 to further improve reliability of the package structure 500.

Referring now to FIGS. 1A-7, a package module 120 may include an interposer 10, a plurality of semiconductor dies 141, 142, 143 on the interposer 10, a module stiffener 150 on the interposer 10 adjacent to the plurality of semiconductor dies 141, 142, 143, and a molding material layer 127 on the interposer 10 around the plurality of semiconductor dies 141, 142, 143 and the module stiffener 150.

In one embodiment, the module stiffener 150 may include a module stiffener ring laterally surrounding the plurality of semiconductor dies 141, 142, 143. In one embodiment, molding material layer 127 may include an inner molding material layer portion 127i inside the module stiffener ring, having a width greater than or equal to 2 mm, and an outer molding material layer portion 127o outside the module stiffener 150 ring, having a width greater than 0.8 mm. In one embodiment, module stiffener 150 may include a stiffener segment, and the molding material layer 127 may be around the stiffener segment. In one embodiment, stiffener segment may include at least one of a linear shape, a rectangular shape, a corner shape or a comb shape. In one embodiment, module stiffener 150 may include at least one of a metal, metal alloy, polymer, semiconductor or composite material. In one embodiment, package module 120 may further include an adhesive layer 160 on the interposer 10, wherein the adhesive layer 160 affixes the module stiffener 150 to the interposer 10. In one embodiment, a height of an upper surface of the module stiffener 150 may be equal to or less than a height of an upper surface of the plurality of semiconductor dies 141, 142, 143. In one embodiment, module stiffener 150 may include a thickness in a range from 100 μm to 5000 μm. In one embodiment, a ratio of a thickness of the module stiffener 150 to a thickness of the plurality of semiconductor dies 141, 142, 143 may be in a range from 0.1:1 to 1:1. In one embodiment, interposer 10 may include one of an organic interposer, an inorganic interposer or a glass substrate. In one embodiment, interposer 10 may include a molding-based interposer including a local silicon interconnect (LSI) 400 interconnecting the plurality of semiconductor dies 141, 142, 143.

Referring again to FIGS. 1A-7, a method of forming a package module 120 may include attaching a plurality of semiconductor dies 141, 142, 143 141, 142, 143 to an interposer 10, attaching a module stiffener 150 to the interposer 10 adjacent to the plurality of semiconductor dies 141, 142, 143, and forming a molding material layer 127 on the interposer 10 around the plurality of semiconductor dies 141, 142, 143 and the module stiffener 150.

In one embodiment, attaching of the module stiffener 150 to the interposer 10 may include attaching a module stiffener ring to the interposer 10, such that the module stiffener ring laterally surrounds the plurality of semiconductor dies 141, 142, 143. In one embodiment, forming of the molding material layer 127 may include forming the molding material layer 127 inside the module stiffener ring and outside the module stiffener ring such that the module stiffener ring may be embedded in the molding material layer 127. In one embodiment, forming of the module stiffener 150 may include forming a stiffener segment, and wherein the forming of the molding material layer 127 may include forming the molding material layer 127 around the stiffener segment. In one embodiment, method may further include forming an adhesive layer 160 on the interposer 10, wherein the attaching of module stiffener 150 to the interposer 10 may include affixing the module stiffener 150 to the interposer 10 with the adhesive layer 160. In one embodiment, method may further include after the forming of the molding material layer 127, performing a dicing process to singulate the package module 120 from an interposer wafer.

Referring again to FIGS. 1A-7, a package structure 500 may include a package substrate 110, and a package module 120 on the package substrate 110. The package module 120 may include an interposer 10, a plurality of semiconductor dies 141, 142, 143 on the interposer 10, a module stiffener 150 on the interposer 10 adjacent to the plurality of semiconductor dies 141, 142, 143, and a molding material layer 127 on the interposer 10 around the plurality of semiconductor dies 141, 142, 143 and the module stiffener 150. In one embodiment, the package structure 500 may further a package stiffener 650 on the package substrate 110 around the package module 120.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package module, comprising:
an interposer;
a plurality of semiconductor dies on the interposer;
a module stiffener on the interposer adjacent to the plurality of semiconductor dies; and
a molding material layer on the interposer around the plurality of semiconductor dies and the module stiffener.

2. The package module of claim 1, wherein the module stiffener comprises a module stiffener ring laterally surrounding the plurality of semiconductor dies.

3. The package module of claim 2, wherein the molding material layer comprises:
an inner molding material layer portion inside the module stiffener ring, having a width greater than or equal to 2 mm; and
an outer molding material layer portion outside the module stiffener ring, having a width greater than 0.8 mm.

4. The package module of claim 1, wherein the module stiffener comprises a stiffener segment, and the molding material layer is around the stiffener segment.

5. The package module of claim 4, wherein the stiffener segment comprises at least one of a linear shape, a rectangular shape, a corner shape or a comb shape.

6. The package module of claim 1, wherein the module stiffener comprises at least one of a metal, metal alloy, polymer, semiconductor or composite material.

7. The package module of claim 1, further comprising:
an adhesive layer on the interposer, wherein the adhesive layer affixes the module stiffener to the interposer.

8. The package module of claim 1, wherein a height of an upper surface of the module stiffener is equal to or less than a height of an upper surface of the plurality of semiconductor dies.

9. The package module of claim 1, wherein the module stiffener comprises a thickness in a range from 100 μm to 5000 μm.

10. The package module of claim 1, wherein a ratio of a thickness of the module stiffener to a thickness of the plurality of semiconductor dies is in a range from 0.1:1 to 1:1.

11. The package module of claim 1, wherein the interposer comprises one of an organic interposer, an inorganic interposer or a glass substrate.

12. The package module of claim 1, wherein the interposer comprises a molding-based interposer including a local silicon interconnect (LSI) interconnecting the plurality of semiconductor dies.

13. A method of forming a package module, the method comprising:
attaching a plurality of semiconductor dies to an interposer;
attaching a module stiffener to the interposer adjacent to the plurality of semiconductor dies; and
forming a molding material layer on the interposer around the plurality of semiconductor dies and the module stiffener.

14. The method of claim 13, wherein the attaching of the module stiffener to the interposer comprises attaching a module stiffener ring to the interposer, such that the module stiffener ring laterally surrounds the plurality of semiconductor dies.

15. The method of claim 14, wherein the forming of the molding material layer comprises forming the molding material layer inside the module stiffener ring and outside the module stiffener ring such that the module stiffener ring is embedded in the molding material layer.

16. The method of claim 13, wherein the forming of the module stiffener comprises forming a stiffener segment, and
wherein the forming of the molding material layer comprises forming the molding material layer around the stiffener segment.

17. The method of claim 13, further comprising:
forming an adhesive layer on the interposer, wherein the attaching of module stiffener to the interposer comprises affixing the module stiffener to the interposer with the adhesive layer.

18. The method of claim 13, further comprising:
after the forming of the molding material layer, performing a dicing process to singulate the package module from an interposer wafer.

19. A package structure, comprising:
a package substrate; and
a package module on the package substrate, comprising:
an interposer;
a plurality of semiconductor dies on the interposer;
a module stiffener on the interposer adjacent to the plurality of semiconductor dies; and
a molding material layer on the interposer around the plurality of semiconductor dies and the module stiffener.

20. The package structure of claim 19, further comprising:
a package stiffener on the package substrate around the package module.
